(19) United States
(12) Patent Application Publication
(10) Pub. No.: US 2026/0250844 A1
(43) Pub. Date: Aug. 27, 2026

(54) THIN FILM PRECURSOR COMPOUND, METHOD OF FORMING THIN FILM USING THIN FILM PRECURSOR COMPOUND, AND SEMICONDUCTOR SUBSTRATE FABRICATED USING METHOD

(71) Applicant: SOULBRAIN CO., LTD., Gyeonggi-do (KR)

(72) Inventors: Ji Hyun NAM, Gyeonggi-do (KR); Jae Sun JUNG, Gyeonggi-do (KR)

(21) Appl. No.: 18/872,442

(22) PCT Filed: Jun. 7, 2023
(86) PCT No.: PCT/KR2023/007765

§ 371 Date: Dec. 6, 2024

(30) Foreign Application Priority Data
Jun. 9, 2023 (KR) 10-2022-0069982

(51) Int. Cl. C23C 16/455; C01B 21/06; C07F 11/00; C23C 16/34; C23C 16/44; H10P 14/40; H10P 14/43

(52) U.S. Cl. CPC C23C 16/45553; C01B 21/062; C07F 11/005; C23C 16/34; C23C 16/4408; H10P 14/412; H10P 14/43

(57) ABSTRACT

The present invention relates to a method of forming a thin film using a thin film precursor compound and a semiconductor substrate and semiconductor device fabricated using the method. According to the present invention, by using a thin film precursor compound represented by Chemical Formula 2, the present invention has an effect of providing a thin film precursor compound having a very fast deposition rate; being easy to handle when injected into a thin film deposition chamber; having very high purity and excellent step coverage due to excellent thermal stability; being capable of reducing thin film growth rate by suppressing side reactions; being capable of significantly improving step coverage and the thickness uniformity of a thin film even when forming a thin film on a substrate having a complex structure; and being capable of significantly improving the electrical properties of a thin film by increasing the density of the thin film, a method of forming a thin film using the thin film precursor compound, and a semiconductor substrate fabricated using the method.

### TECHNICAL FIELD

The present invention relates to a thin film precursor compound, a method of forming a thin film using the thin film precursor compound, and a semiconductor substrate fabricated using the method. More particularly, the present invention relates to a thin film precursor compound having a very fast deposition rate due to strong volatility in a liquid state at room temperature; being easy to handle when injected into a thin film deposition chamber; having very high purity and excellent step coverage due to excellent thermal stability; being capable of reducing thin film growth rate by suppressing side reactions; being capable of significantly improving step coverage and the thickness uniformity of a thin film even when forming a thin film on a substrate having a complex structure; and being capable of significantly improving the electrical properties of a thin film by increasing the density of the thin film, a method of forming a thin film using the thin film precursor compound, and a semiconductor substrate fabricated using the method.

### BACKGROUND ART

In conventional semiconductor devices with a two-dimensional planar structure, as the integration level increases, the cell gap narrows and the occurrence of leakage current increases. To overcome this problem, a 3D V-NAND with a high integration level has been developed by stacking circuits in a three-dimensional stereoscopic structure. In addition, when a thin film precursor material such as WF₆ used as an electrode of a semiconductor device is applied to CVD (H₂ reduction), voids are generated due to fluorine, creating a seam in a cell, reducing device performance, and increasing resistance as the number of NAND stages increases. To overcome these problems, Mo compounds with low resistivity have been applied. However, the Mo compounds currently used, such as MoO₂Cl₂, have a problem in that the amount of solid sublimated at room temperature is not constant, making it difficult to supply stably.

### RELATED ART DOCUMENTS

### Patent Documents

KR 2006-0037241 A

### DISCLOSURE

### Technical Problem

Therefore, the present invention has been made in view of the above problems, and it is one object of the present invention to provide a thin film precursor compound having a very fast deposition rate due to strong volatility in a liquid state at room temperature; being easy to handle when injected into a thin film deposition chamber; having very high purity and excellent step coverage due to excellent thermal stability; being capable of reducing thin film growth rate by suppressing side reactions; and being capable of removing process by-products in a thin film to significantly improve step coverage and the thickness uniformity of the thin film even when forming the thin film on a substrate having a complex structure, a method of forming a thin film using the thin film precursor compound, and a semiconductor substrate fabricated using the method.

The above and other objects can be accomplished by the present invention described below.

### Technical Solution

In accordance with one aspect of the present invention, provided is a thin film precursor compound represented by Chemical Formula 2:

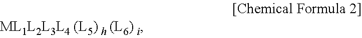

wherein M includes one or more selected from the group consisting of molybdenum (Mo), tungsten (W), chromium (Cr), and seaborgium (Sg) and has charges of 0, +3, +4, +5, and +6 and a coordination number of 6, L₁, L₂, L₃, L₄, L₅, and L₆ are independently selected from the group consisting of NRaRb; ORc; NRc; CO; RdCp; amidinate; guadinate; ethylenediamine; propylenediamine; and a linear or cyclic saturated or unsaturated hydrocarbon having 3 to 15 carbon atoms and substituted with one or more nitrogen (N), oxygen (O), phosphorus (P), or sulfur (S), Cp is cyclopentadienyl, Ra, Rb, Rc, and Rd are independently hydrogen or alkyl having 1 to 12 carbon atoms, h and i are independently 0 or 1, an overall oxidation number of the compound is an integer from −2 to 6, and one or more ligands selected from L₁, L₂, L₃, L₄, L₅, and L₆ are linear or cyclic saturated or unsaturated hydrocarbons having 3 to 15 carbon atoms and substituted with one or more nitrogen (N), oxygen (O), phosphorus (P), or sulfur (S).

The thin film precursor compound may be a compound represented by Chemical Formula 3 or 4 below.

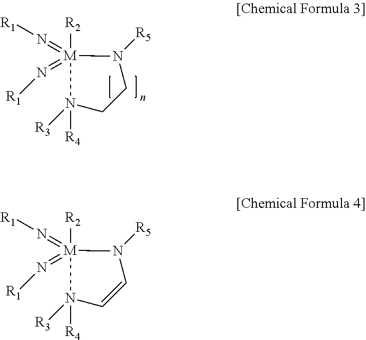

In Chemical Formulas 3 and 4, M includes one or more selected from the group consisting of molybdenum (Mo), tungsten (W), chromium (Cr), and seaborgium (Sg) and has charges of 0, +3, +4, +5, and +6 and a coordination number of 6, R₁, R₂, R₃, R₄, and R₅ are independently selected from the group consisting of hydrogen, a dimethylamine group, a substituted or unsubstituted alkyl group having 1 to 7 carbon atoms, and a substituted or unsubstituted alkoxy group having 1 to 7 carbon atoms, and n is an integer from 0 to 2.

The thin film precursor compound may be obtained using a compound represented by Chemical Formula 1 below as an intermediate.

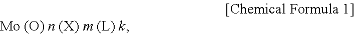

wherein Mo is molybdenum, O is oxygen, X is a halogen, L is a ligand, n is an integer from 0 to 2, m is an integer from 2 to 6, and k is an integer from 1 to 3.

The ligand may be a linear or cyclic saturated hydrocarbon having 3 to 15 carbon atoms and substituted with one or more nitrogen (N), oxygen (O), phosphorus (P), or sulfur (S) elements.

The intermediate may be (tBuN=)₂MoCl₂(DAE) (Here, DAE is a dialkoxyethane having 1 to 15 carbon atoms).

The thin film precursor compound may be liquid and have volatility at 20° C. under 1 bar.

In accordance with another aspect of the present invention, provided is a method oof forming a thin film, the method including injecting a thin film precursor compound represented by Chemical Formula 2 into a chamber and depositing the thin film precursor compound on a surface of a loaded substrate:

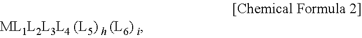

wherein M includes one or more selected from the group consisting of molybdenum (Mo), tungsten (W), chromium (Cr), and seaborgium (Sg) and has charges of 0, +3, +4, +5, and +6 and a coordination number of 6, L₁, L₂, L₃, L₄, L₅, and L₆ are independently selected from the group consisting of NRaRb; ORc; NRc; CO; RdCp; amidinate; guadinate; ethylenediamine; propylenediamine; and a linear or cyclic saturated or unsaturated hydrocarbon having 3 to 15 carbon atoms and substituted with one or more nitrogen (N), oxygen (O), phosphorus (P), or sulfur (S), Cp is cyclopentadienyl, Ra, Rb, Rc, and Rd are independently hydrogen or alkyl having 1 to 12 carbon atoms, h and i are independently 0 or 1, an overall oxidation number of the compound is an integer from −2 to 6, and one or more ligands selected from L₁, L₂, L₃, L₄, L₅, and L₆ are linear or cyclic saturated or unsaturated hydrocarbons having 3 to 15 carbon atoms and substituted with one or more nitrogen (N), oxygen (O), phosphorus (P), or sulfur (S).

The depositing may include vaporizing the thin film precursor compound and adsorbing the thin film precursor compound onto a surface of a substrate loaded into a chamber; purging an inside of the chamber with a purge gas; supplying a reaction gas into the chamber; and purging the inside of the chamber with a purge gas.

In the depositing, the thin film precursor compound and the reaction gas may be simultaneously injected into the substrate loaded into the chamber.

The depositing may performed by atomic layer deposition (ALD process), chemical vapor deposition (CVD process), plasma atomic layer deposition (PEALD process), or plasma chemical vapor deposition (PECVD process).

In the method of forming a thin film, a nitrating agent, oxidizing agent, or reducing agent may be used as the reaction gas.

The thin film may include a metal nitride thin film, a metal oxide thin film, or a metal thin film.

In accordance with still another aspect of the present invention, provided is a semiconductor substrate fabricated using the method of forming a thin film described above.

In accordance with yet another aspect of the present invention, provided is a semiconductor device including the semiconductor substrate described above.

### Advantageous Effects

According to the present invention, the present invention has an effect of providing a thin film precursor compound having a very fast deposition rate due to strong volatility in a liquid state at room temperature; being easy to handle when injected into a thin film deposition chamber; having very high purity and excellent step coverage due to excellent thermal stability; being capable of reducing thin film growth rate by suppressing side reactions; and being capable of removing process by-products in a thin film to significantly improve step coverage and the thickness uniformity of the thin film even when forming the thin film on a substrate having a complex structure, a method of forming a thin film using the thin film precursor compound, and a semiconductor substrate fabricated using the method.

### DESCRIPTION OF DRAWINGS

FIG. 1 is the NMR spectrum of a thin film precursor compound synthesized in Synthesis Example 2.

FIG. 2 is a diagram showing the results of thermogravimetric analysis (DSC-TG analysis) of a thin film precursor compound synthesized in Synthesis Example 2.

FIG. 3 is a diagram showing the results of differential scanning calorimetry (DSC) analysis of a thin film precursor compound synthesized in Synthesis Example 2.

FIG. 4 is a schematic drawing of a deposition apparatus for performing atomic layer deposition using a thin film precursor compound as in Example 1 or 2.

FIG. 5 is a TEM image measuring the thickness of a cross-section of a thin film formed using the deposition apparatus of FIG. 4 using the thin film precursor compound synthesized in Synthesis Example 2. The left drawing corresponds to the deposition condition of 350° C., and the right drawing corresponds to the deposition condition of 400° C.

### BEST MODE

Hereinafter, a thin film precursor compound of the present invention, a method of forming a thin film using the thin film precursor compound, and a semiconductor substrate fabricated using the method are described in detail.

The present inventors confirmed that, when a thin film precursor compound having a predetermined structure was adsorbed onto the surface of a substrate loaded into an ALD chamber, the deposition rate of the thin film precursor compound was significantly increased due to strong volatility in a liquid state at room temperature. In addition, the thin film precursor compound could be easily handled when injected into the thin film deposition chamber, and had very high purity due to excellent thermal stability. In addition, the step coverage and the thin film uniformity were improved. In addition, halides remaining as process by-products were significantly reduced, and the density and resistivity of a thin film were greatly improved. Based on these results, the present inventors conducted further studies to complete the present invention.

A thin film precursor compound according to one embodiment of the present invention is a compound represented by Chemical Formula 2 below.

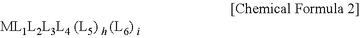

In Chemical Formula 2, M includes one or more selected from the group consisting of molybdenum (Mo), tungsten (W), chromium (Cr), and seaborgium (Sg) and has charges of 0, +3, +4, +5, and +6 and a coordination number of 6, L₁, L₂, L₃, L₄, L₅, and L₆ are independently selected from the group consisting of NRaRb; ORc; NRc; CO; RdCp; amidinate; guadinate; ethylenediamine; propylenediamine; and a linear or cyclic saturated or unsaturated hydrocarbon having 3 to 15 carbon atoms and substituted with one or more nitrogen (N), oxygen (O), phosphorus (P), or sulfur (S), Cp is cyclopentadienyl, Ra, Rb, Rc, and Rd are independently hydrogen or alkyl having 1 to 12 carbon atoms, h and i are independently 0 or 1, an overall oxidation number of the compound is an integer from −2 to 6, and one or more ligands selected from L₁, L₂, L₃, L₄, L₅, and L₆ are linear or cyclic saturated or unsaturated hydrocarbons having 3 to 15 carbon atoms and substituted with one or more nitrogen (N), oxygen (O), phosphorus (P), or sulfur (S). In this case, the deposition rate of the thin film precursor compound may be greatly increased due to strong volatility in a liquid state at room temperature, the thin film precursor compound may be easily handled when injected into the thin film deposition chamber, the purity of the thin film precursor compound may be very high due to excellent thermal stability, and step coverage may be improved.

The thin film precursor compound may be selected from compounds represented by Chemical Formulas 3 and 4.

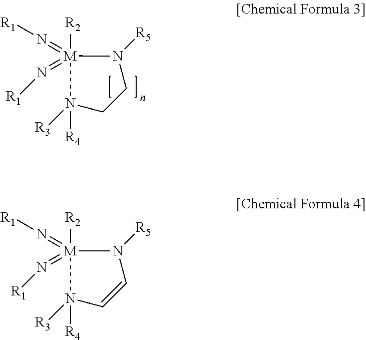

In Chemical Formulas 3 and 4, M includes one or more selected from the group consisting of molybdenum (Mo), tungsten (W), chromium (Cr), and seaborgium (Sg) and has charges of 0, +3, +4, +5, and +6 and a coordination number of 6, R₁, R₂, R₃, R₄, and R₅ are independently selected from the group consisting of hydrogen, a dimethylamine group, a substituted or unsubstituted alkyl group having 1 to 7 carbon atoms, and a substituted or unsubstituted alkoxy group having 1 to 7 carbon atoms, and n is an integer from 0 to 2. In this case, the deposition rate of the thin film precursor compound may be greatly increased due to strong volatility in a liquid state at room temperature, and the thin film precursor compound may be easily handled when injected into the thin film deposition chamber. In particular, selective bonding may be induced, so that contamination of a thin film may be minimized. In addition, the thin film precursor compound may be easily removed using a reaction gas. Accordingly, the purity may be high, and the step coverage may be excellent.

In Chemical Formulas 3 and 4, M may include one or more selected from the group consisting of molybdenum (Mo), tungsten (W), chromium (Cr), and seaborgium (Sg) and may have charges of 0, +3, +4, +5, and +6 and a coordination number of 6.

In Chemical Formulas 3 and 4, R₁, R₂, R₃, R₄, and R₅ may be independently selected from the group consisting of H, C₁ to C₇ substituted or unsubstituted alkyl, C₁ to C₇ substituted or unsubstituted alkoxy, and dimethylamine.

In Chemical Formulas 3 and 4, R₁ and R₅ may be independently selected from H and C₁ to C₇ substituted or unsubstituted alkyl. For example, R₁ and R₅ may be independently selected from methyl, ethyl, propyl, iso-propyl, sec-butyl, iso-butyl, tert-butyl, sec-pentyl, iso-pentyl, tert-pentyl, neo-pentyl, iso-hexyl, sec-hexyl, tert-hexyl, neo-butyl, iso-butyl, tert-butyl, tert-pentyl, neo-pentyl, hexane, iso-hexane, neo-hexane, heptane, iso-heptane, and neo-heptane.

In Chemical Formulas 3 and 4, R₂ may be selected from the group consisting of H and C₁ to C₇ substituted or unsubstituted alkyl. For example, R₂ may be selected from methyl, ethyl, propyl, iso-propyl, sec-butyl, iso-butyl, tert-butyl, sec-pentyl, iso-pentyl, tert-pentyl, neo-pentyl, iso-hexyl, sec-hexyl, tert-hexyl, neo-butyl, iso-butyl, tert-butyl, tert-pentyl, neo-pentyl, hexane, iso-hexane, neo-hexane, heptane, iso-heptane, and neo-heptane.

In Chemical Formulas 3 and 4, R₃ and R₄ may be independently selected from the group consisting of H and Ci to C₇ substituted or unsubstituted alkyl. For example, R₃ and R₄ may be independently selected from methyl, ethyl, propyl, iso-propyl, sec-butyl, iso-butyl, tert-butyl, sec-pentyl, iso-pentyl, tert-pentyl, neo-pentyl, iso-hexyl, sec-hexyl, tert-hexyl, neo-butyl, iso-butyl, tert-butyl, tert-pentyl, neo-pentyl, hexane, iso-hexane, neo-hexane, heptane, iso-heptane, and neo-heptane.

In the present disclosure, for example, the C₁ to C₇ alkyl may include one selected from the group consisting of a methyl group, an ethyl group, an n-propyl group, an iso-propyl group, an n-butyl group, an iso-butyl group, a sec-butyl group, a tert-butyl group, an n-pentyl group, an iso-pentyl group, a neo-pentyl group, a tert-butyl group, and isomers thereof, without being limited thereto.

In the present disclosure, for example, the C₁ to C₇ alkoxy may include one selected from the group consisting of a methoxy group, an ethoxy group, an n-propoxy group, an iso-propoxy group, an n-butoxy group, an iso-butoxy group, a sec-butoxy group, a tert-butoxy group, an n-pentoxy group, an iso-pentoxy group, a neo-pentoxy group, a tert-butoxy group, and isomers thereof, without being limited thereto.

In Chemical Formulas 3 and 4, n may be an integer from 0 to 2.

As a specific example, in Chemical Formulas 3 and 4, M may be molybdenum (Mo), R₁ and R₅ may be independently selected from the group consisting of H and C₁ to C₇ substituted or unsubstituted alkyl, R₃ and R₄ may be independently selected from the group consisting of H and C₁ to C₅ substituted or unsubstituted alkyl, R₂ may be selected from the group consisting of H, C₁ to C₅ substituted or unsubstituted alkyl, C₁ to C₇ substituted or unsubstituted alkoxy, and dimethylamine, and n may be an integer from 0 to 2.

In addition, M may be tungsten (W), R₁ and R₅ may be independently selected from the group consisting of H and C₁ to C₇ substituted or unsubstituted alkyl, R₃ and R₄ may be independently selected from the group consisting of H and C₁ to C₅ substituted or unsubstituted alkyl, R₂ may be selected from the group consisting of H, C₁ to C₅ substituted or unsubstituted alkyl, C₁ to C₇ substituted or unsubstituted alkoxy, and dimethylamine, and n may be an integer from 0 to 2.

In addition, M may be chromium (Cr), R₁ and R₅ may be independently selected from the group consisting of H and C₁ to C₇ substituted or unsubstituted alkyl, R₃ and R₄ may be independently selected from the group consisting of H and C₁ to C₅ substituted or unsubstituted alkyl, R₂ may be selected from the group consisting of H, C₁ to C₅ substituted or unsubstituted alkyl, C₁ to C₇ substituted or unsubstituted alkoxy, and dimethylamine, and n may be an integer from 0 to 2.

For example, the thin film precursor compound according to one embodiment of the present invention may be obtained using a compound represented by Chemical Formula 1 below as an intermediate.

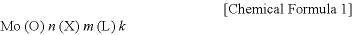

In Chemical Formula 1, Mo is molybdenum, O is oxygen, X is a halogen, L is a ligand, n is an integer from 0 to 2, m is an integer from 2 to 6, and k is an integer from 1 to 3. In this case, the deposition rate of the thin film precursor compound may be greatly increased due to strong volatility in a liquid state at room temperature, and the thin film precursor compound may be easily handled when injected into the thin film deposition chamber. In particular, selective bonding may be induced, so that contamination of a thin film may be minimized. In addition, the thin film precursor compound may be easily removed using a reaction gas. Accordingly, the purity may be high, and the step coverage may be excellent.

When the ligand is a linear or cyclic saturated hydrocarbon having 3 to 15 carbon atoms and substituted with one or more nitrogen (N), oxygen (O), phosphorus (P), or sulfur (S) elements, the deposition rate of the thin film precursor compound may be greatly increased due to strong volatility in a liquid state at room temperature, and the thin film precursor compound may be easily handled when injected into the thin film deposition chamber. In particular, selective bonding may be induced, so that contamination of a thin film may be minimized. In addition, the thin film precursor compound may be easily removed using a reaction gas. Accordingly, the purity may be high, and the step coverage may be excellent.

The intermediate may be prepared preferably by substitution reaction between a molybdenum compound selected from the group consisting of MoX₆, MoO₂X₂, MoOX₄, MoO₂X₂, and MoO₂X₄ (X represents halogen) and the ligand.

As a specific example, the ligand may be t-butyl amine, chlorotrimethylsilane, and 1,2-dimethoxyethane, which are used in Synthesis Example 1 described below, without being limited thereto.

The intermediate may be preferably (tBuN=)₂MoCl₂(DAE) (DAE is a dialkoxyethane having 1 to 15 carbon atoms). For example, DAE may be dimethoxyethane (DME), diethoxyethane (DEE), or diethylmethoxy ethane (DEME), without being limited thereto.

In the present invention, in the case of the thin film precursor compound obtained using the above-described intermediate, the deposition rate of the thin film precursor compound may be greatly increased due to strong volatility in a liquid state at room temperature, and the thin film precursor compound may be easily handled when injected into the thin film deposition chamber. In particular, selective bonding may be induced, so that contamination of a thin film may be minimized. In addition, the thin film precursor compound may be easily removed using a reaction gas. Accordingly, the purity may be high, and the step coverage may be excellent.

Preferably, the thin film precursor compound is liquid and has volatility at 20° C. under 1 bar. In this case, the deposition rate may be significantly increased. In addition, the thin film precursor compound may be easy to handle when injected into a thin film deposition chamber, may have very high purity and excellent step coverage due to excellent thermal stability, may reduce thin film growth rate by suppressing side reactions, may significantly improve step coverage and the thickness uniformity of a thin film even when forming a thin film on a substrate having a complex structure, and may significantly improve the electrical properties of a thin film by increasing the density of the thin film.

For reference, reactants used in atomic layer deposition (ALD) should have high volatility, stability, and high reactivity. According to atomic layer deposition (ALD), the reactant materials are supplied separately, and a thin film less than a monolayer is grown by surface reaction during one deposition cycle, and the ligand of the reactant material adsorbed on the substrate is removed through a chemical reaction with other reactant materials supplied later. Therefore, when heating the precursor, which is a reactant for atomic layer deposition, the liquid state is much more advantageous in terms of reaction speed and process than the solid state.

Here, unless otherwise specified, volatility refers to volatility exhibited in a chamber at 300° C. or higher. In this case, the compound may be evenly distributed on the substrate.

The thin film precursor compound according to one embodiment of the present invention may not only exist in a liquid state at room temperature by coordinating a hetero ligand to a central metal, but also exhibit improved vapor pressure.

Since each thin film precursor compound represented by Chemical Formula 1, as a specific example, Chemical Formula 3 or 4 has excellent thermal stability, low-temperature deposition is also possible. For reference, when the —NR₅—C═C—NR₃R₄ fragment included in a hetero ligand is expanded, a chain becomes longer and coordination bonding becomes possible on a side other than a central metal side. Accordingly, the compound may not be suitable for deposition by chemical vapor deposition (CVD), organometal chemical vapor deposition (MOCVD), low-pressure vapor deposition (LPCVD), plasma-enhanced vapor deposition (PECVD), atomic layer deposition (ALD), or plasma-enhanced atomic layer deposition (PEALD).

On the other hand, in the case of the thin film precursor compound represented by Chemical Formula 1 obtained using the intermediate, as a specific example, the thin film precursor compounds represented by Chemical Formulas 3 and 4, since purification is performed at relatively low temperatures of 170 to 180° C. under 0.4 torr, the compounds have a vapor pressure that is relatively favorable for deposition evaluation and may provide a liquid phase.

In addition, in the case of the thin film precursor compound represented by Chemical Formula 1 obtained using the intermediate, as a specific example, the thin film precursor compounds represented by Chemical Formulas 3 and 4, the compounds have low reactivity with moisture, so there is no risk of spontaneous combustion, making the compounds easy to handle. In addition, since the compounds have high vapor pressure, the compounds may be used to form thin films using deposition processes such as chemical vapor deposition and atomic layer deposition.

In particular, the properties of the thin film according to the process temperature during deposition show an ALD window range in the temperature range of 330 to 370° C., so that the thin film may be used as an ALD precursor having a constant deposition temperature in the corresponding range, thereby reducing the process cost.

The method of forming a thin film according to the present invention includes a step of injecting a thin film precursor compound represented by Chemical Formula 1, as a specific example, the compound represented by Chemical Formula 3 or 4, into a chamber and depositing the thin film precursor compound on the surface of a loaded substrate. In this case, the thin film precursor compound may have a very fast deposition rate due to strong volatility in a liquid state at room temperature, may be easy to handle when injected into a thin film deposition chamber, may have very high purity and excellent step coverage due to excellent thermal stability, may suppress side reactions and reduce thin film growth rate, and may remove process by-products in a thin film to significantly improve step coverage and the thickness uniformity of the thin film even when forming the thin film on a substrate having a complex structure.

The method of forming a thin film of the present invention may include a step of vaporizing the thin film precursor compound represented by Chemical Formula 1, as a specific example, the thin film precursor compound represented by Chemical Formula 3 or 4, and adsorbing the thin film precursor compound onto the surface of a substrate loaded into a chamber; a step of purging the inside of the chamber with a purge gas; a step of supplying a reaction gas into the chamber; and a step of purging the inside of the chamber with a purge gas.

In the deposition step, the thin film precursor compound and the reaction gas may be sequentially or simultaneously injected onto the substrate loaded into the chamber.

The method of forming a thin film may be performed in the same manner as in the conventional method of forming a metal thin film, except that the thin film precursor compound represented by Chemical Formula 1, as a specific example, the thin film precursor compound represented by Chemical Formula 3 or 4, is used as a thin film precursor compound. For example, the method of forming a thin film of the present invention may be performed by atomic layer deposition (ALD process), chemical vapor deposition (CVD process), plasma atomic layer deposition (PEALD process), or plasma chemical vapor deposition (PECVD process), preferably chemical vapor deposition or atomic layer deposition, without being limited thereto.

Specifically, the metal thin film may be formed by gasifying one or more of the thin film precursor compound represented by Chemical Formula 1, as a specific example, the thin film precursor compounds represented by Chemical Formulas 3 and 4, applying the thin film precursor compound onto a substrate on which a metal thin film layer is formed, such as a TiN, SiO₂, and Si₃N₄ substrate, and decomposing the precursor.

The thin film precursor compound may be injected onto the substrate under temperature conditions appropriate to the material properties, and the deposition process conditions may vary depending on deposition efficiency.

The thin film precursor compound is preferably injected in a heated state considering the efficiency of the deposition process. For example, the thin film precursor compound may be injected onto a substrate at 50 to 400° C., as a specific example, at 50 to 350° C. for 1 to 20 seconds.

At this time, the method of gasifying the thin film precursor compound may include a step of purging the unabsorbed thin film precursor compound using an inert gas and then injecting a reaction gas.

Specifically, a method of directly vaporizing a thin film precursor compound, or a method of injecting a thin film precursor compound into a constant temperature vessel and then supplying an inert gas such as helium, neon, argon, krypton, xenon, or nitrogen to gasify the compound may be used.

The decomposition process of the thin film precursor compound may be performed by methods such as heat treatment, plasma treatment, or light irradiation. At this time, the process may be performed in the presence of a reactive gas such as water vapor, oxygen, ozone, hydrogen, ammonia, hydrazine, or silane. When the decomposition process of a thin film precursor compound is performed using an oxidizing agent such as water vapor, oxygen, or ozone as a reaction gas, a metal oxide thin film may be formed. When the decomposition process of a thin film precursor compound is performed in the presence of a reducing agent such as hydrogen, ammonia, hydrazine, or silane as a reaction gas, a metal thin film may be formed. When the decomposition process of a thin film precursor compound is performed using a nitrating agent such as nitrogen, ammonia, or hydrazine as a reaction gas, a metal nitride thin film may be formed.

As a specific example, the process of decomposing the thin film precursor compound by heat treatment may be performed at 100 to 1000° C., and the deposition temperature of the substrate may be, for example, 50 to 400° C., preferably 200 to 400° C.

For example, the feeding time of the thin film precursor compound on the substrate surface may be preferably 1 to 10 seconds per cycle, more preferably 1 to 5 seconds per cycle, still more preferably 2 to 5 seconds per cycle, still more preferably 2 to 4 seconds per cycle. Within this range, step coverage and economic efficiency may be excellent.

For example, the feeding time of the thin film precursor compound described above may be determined based on a chamber volume of 15 to 20 L and a flow rate of 0.5 to 5 mg/s, and more specifically, based on a chamber volume of 18 L and a flow rate of 1 to 2 mg/s. When the chamber volume and flow rate are varied, the feeding time may also be adjusted to optimize the deposition efficiency.

The thin film precursor compound may be transported into the chamber preferably by the VFC method, the direct liquid injection (DLI) method or the liquid delivery system (LDS) method, more preferably by the LDS method.

In the present disclosure, purging may be performed at preferably 1,000 to 10,000 sccm, more preferably 2,000 to 7,000 sccm, still more preferably 2,500 to 6,000 sccm. Within this range, the thin film growth rate per cycle may be reduced to a desirable range and process by-products may be reduced.

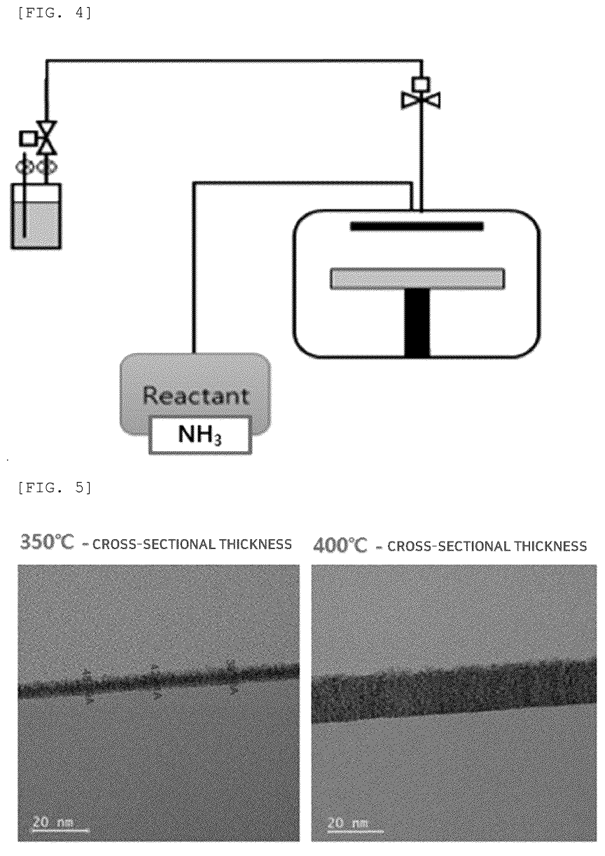

Deposition according to the present invention may be performed using a deposition apparatus commonly used in the art, and in the embodiment described below, a thin film may be manufactured by atomic layer deposition (ALD) using the deposition apparatus shown in FIG. 4 below.

FIG. 4 below is a schematic drawing of a deposition apparatus for performing atomic layer deposition according to the present invention using NH₃ gas as a nitrating agent. The source line and reaction gas line are formed separately to maximize the properties of a material by controlling the temperature according to each characteristic. However, the use of a device in which the source line and the reaction gas line are integrated is not outside the scope of the present invention.

In addition, as a thin film forming apparatus capable of implementing the thin film forming method, the present invention may include a thin film forming apparatus including an ALD chamber, a first vaporizer for vaporizing a thin film precursor compound, a first transport means for transporting the vaporized thin film precursor compound into the ALD chamber, and a second transport means for transporting a reaction gas into the ALD chamber. Here, vaporizers and transport means are not particularly limited as long as the vaporizers and transport means are vaporizers and transport means commonly used in the technical field to which the present invention belongs.

In the method of forming a metal-containing thin film according to the present invention, a deposition process may be performed at a lower temperature than before by using a thin film precursor compound having excellent thermal stability. In addition, the crystallinity may be excellent because there is no particle contamination or carbon impurity contamination caused by thermal decomposition of the precursor. Accordingly, a metal thin film having high purity or a metal oxide or metal nitride thin film may be formed at a high deposition rate without the generation of process by-products.

In the thin film forming method according to the present invention, a film quality-improving agent, a thin film growth inhibitor, or a thin film growth activator known in the art may be used when necessary.

In addition, this specification describes using an ALD chamber or an ALD process, but the present invention is not limited thereto. For reference, atomic layer deposition (ALD process) is very useful for manufacturing integrated circuits (ICs) that require high aspect ratios. In particular, atomic layer deposition has advantages such as excellent conformality, uniformity, and precise thickness control due to the self-limiting thin film growth mechanism.

For example, the method of forming a thin film may be performed at a deposition temperature of 50 to 900° C., preferably 300 to 700° C., more preferably 350 to 600° C., still more preferably 400 to 550° C., still more preferably 400 to 500° C. Within this range, a thin film with excellent film quality may be formed while implementing the ALD process characteristics.

For example, the method of forming a thin film may be performed under a deposition pressure of 0.1 to 10 Torr, preferably 0.5 to 5 Torr, most preferably 1 to 3 Torr. Within this range, a thin film of uniform thickness may be obtained.

In the present disclosure, the deposition temperature and deposition pressure may be measured as temperature and pressure formed within the deposition chamber, or as temperature and pressure applied to the substrate within the deposition chamber.

The method of forming a thin film may preferably include a step of increasing the temperature inside the chamber to the deposition temperature before introducing the thin film precursor compound into the chamber; and/or a step of performing purging by injecting an inert gas into the chamber before introducing the thin film precursor compound into the chamber.

As a specific example, according to the method of forming a thin film, first, a substrate on which a thin film is formed is placed in a deposition chamber capable of atomic layer deposition.

The substrate may include a semiconductor substrate such as a silicon substrate or silicon oxide.

A conductive layer or insulating layer may be further formed on top of the substrate.

To deposit a thin film on the substrate positioned in the deposition chamber, the thin film precursor compound described above is prepared.

Then, the prepared thin film precursor compound is injected into a vaporizer, changed into a vapor phase, and transferred to the deposition chamber to be adsorbed on the substrate, and the unadsorbed thin film precursor compound is purged.

In the present disclosure, for example, the method of transporting the thin film precursor compound into the deposition chamber may include the vapor flow control (VFC) method of transporting evaporated gas using a mass flow Controller (MFC) or the liquid delivery system (LDS) in which liquid is transported using a liquid mass flow controller (LMFC), preferably the LDS.

At this time, a mixed gas containing one or more selected from argon (Ar), nitrogen (N₂), and helium (He) may be used as a transport gas or dilution gas to move the thin film precursor compound onto the substrate, but the present invention is not limited thereto.

In the present disclosure, as the purge gas, an inert gas may be used, preferably a carrier gas or a dilution gas.

Next, a reaction gas is supplied. A reaction gas is not particularly limited as long as the reaction gas is a reaction gas commonly used in the technical field to which the present invention belongs, and may preferably include a reducing agent, a nitrating agent or an oxidizing agent. The reducing agent reacts with the thin film precursor compound adsorbed on the substrate to form a metal thin film, a metal nitride thin film is formed by the nitrating agent, and a metal oxide thin film is formed by the oxidizing agent.

Next, the unreacted residual reaction gas is purged using an inert gas. Accordingly, both the excess reaction gas and the generated byproducts may be removed.

As described above, a unit cycle consists of the steps of adsorbing a thin film precursor compound onto a substrate, purging the non-adsorbed thin film-forming composition, supplying a reaction gas, and purging the residual reaction gas, and the unit cycle may be repeated to form a thin film of a desired thickness.

For example, the unit cycle may be repeated 100 to 1000 times, preferably 100 to 500 times, more preferably 150 to 300 times. Within this range, the desired thin film properties may be well expressed.

When using a molybdenum-based thin film precursor (e.g., MoO₂Cl₂) compound that is in a solid state at 20° C. and atmospheric pressure used in the conventional ALD process, solids do not sublimate well and react with reaction gases (e.g., NH₃) to leave process by-products such as NH₄Cl and HCl in the thin film, which causes corrosion or deterioration and degrades the performance of the substrate. However, when using the thin film precursor compound according to the present invention, thermal stability may be improved, and thus the deposition rate may be increased. In addition, since process by-products such as NH₄Cl and HCl generated by reaction with reaction gas (e.g., NH₃) are removed together with the thin film precursor compound, corrosion or deterioration of the substrate may be prevented, and step coverage and uniformity of thin film thickness may be improved. In addition, the density of the thin film may be improved, providing excellent electrical characteristics.

According to another embodiment of the present invention, a metal-containing film manufactured by the method of forming a thin film is provided.

The metal-containing film may be a metal nitride film, a metal oxide film, or a metal film depending on a reaction gas used. The metal-containing film may have precise thickness control, and may have high conformity and thin film uniformity even when the film has a complex structure.

A semiconductor substrate of the present invention is fabricated by the method of forming a thin film of the present invention. In this case, by improving the deposition rate, process by-products within the thin film may be eliminated, which prevents corrosion or deterioration. In addition, step coverage and thickness uniformity of the thin film may be improved.

The semiconductor substrate includes a substrate including a wafer; and a thin film formed on the substrate. Here, the thin film may be the thin film manufactured by the method described above.

The manufactured thin film preferably has a thickness of 20 nm or less, a resistivity value of 0.1 to 400 μΩ cm, a halogen content of 10,000 ppm or less, and a step coverage of 90% or more. Within this range, the thin film may have excellent performance as a diffusion barrier, and corrosion of metal wiring materials may be reduced, but the present invention is not limited thereto.

For example, the thin film may have a thickness of 5 to 20 nm, preferably 10 to 20 nm, more preferably 15 to 18.5 nm, still more preferably 17 to 18.5 nm. Within this range, thin film properties may be excellent.

For example, the thin film may have a resistivity value of 0.1 to 400 μΩ·cm, preferably 50 to 400 μΩ·cm, more preferably 100 to 300 μΩ·cm. Within this range, thin film properties may be excellent.

The thin film may have a halogen content of preferably 9,000 ppm or less or 1 to 9,000 ppm, more preferably 8,500 ppm or less or 100 to 8,500 ppm, still more preferably 8,200 ppm or less or 1,000 to 8,200 ppm. Within this range, thin film properties may be excellent, and corrosion of metal wiring materials may be reduced.

For example, the thin film may have a step coverage of 80% or more, preferably 90% or more, more preferably 92% or more. Within this range, even thin films with complex structures may be easily deposited on a substrate, which has the advantage of being applicable to next-generation semiconductor devices.

For example, the prepared thin film may be an Mo thin film, MoN thin film, MoO thin film, MoS₂ thin film, or MoSe₂ thin film.

According to another embodiment of the present invention, a semiconductor device including the semiconductor substrate is provided.

For example, the semiconductor device may be low resistive metal gate interconnects, a high aspect ratio 3D metal-insulator-metal (MIM) capacitor, a DRAM trench capacitor, Gate-All-Around (GAA), or 3D NAND.

Hereinafter, the present invention will be described in more detail with reference to the following preferred examples. However, these examples are provided for illustrative purposes only and should not be construed as limiting the scope and spirit of the present invention. In addition, it will be apparent to those skilled in the art that various changes and modifications may be made without departing from the spirit and scope of the present invention, and such changes and modifications are also within the scope of the appended claims.

### EXAMPLES

### Synthesis Example 1: Synthesis of (tBuN=)₂MoCl₂(DME)

(tBuN=)₂MoCl₂DME was synthesized from Na₂MoO₄ according to Reaction Formula 1 below.

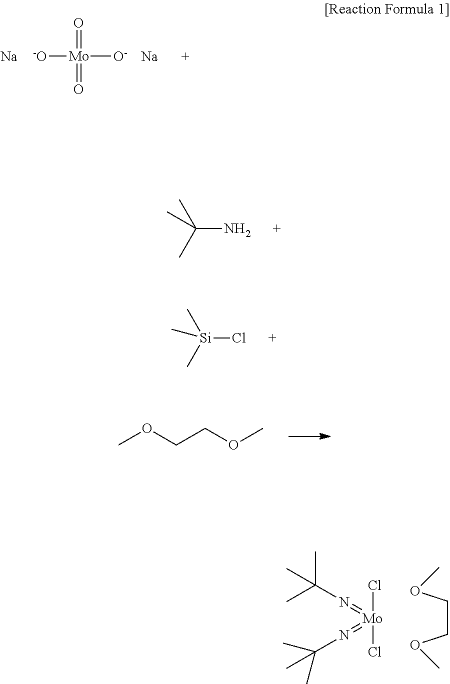

Specifically, 67 g (486 mmol) of Na₂MoO₄, 1 L of 1, 2-dimethoxyethane, 180 mL of trimethylamine, 374 mL of chlorotrimethylsilane, and 80 mL of t-butylamine were sequentially fed into a 3 L reaction flask under a dry argon gas atmosphere, and reaction was performed for 24 while refluxing at 65° C., and then The completion of the reaction was confirmed by NMR.

Unless otherwise stated, all materials used in Reaction Formula 1 are synthetic and purified to high purity (99% or more). The obtained yellow solution was filtered, washed with hexane, and the filtrate was vacuum-dried. The obtained solid was washed repeatedly with hexane, and 27 g (yield: 21 wt %) of (tBuN=)₂MoCl₂(DME) was obtained. Through NMR analysis of the product, it was confirmed that an intermediate having the structure of (tBuN=)₂MoCl₂DME was obtained.

¹H NMR (in C₆D₆) (3.48 ppm, s, 6H), (3.22 ppm, s, 4H) (1.42 ppm, s, 18H)

### Synthesis Example 2: Synthesis of (tBuN=)₂Mo (TBDMAE) (DMA)

Using the (tBuN=)₂MoCl₂(DME) obtained in Synthesis Example 1, (tBuN=)₂Mo(TBDMAE) (DMA) was synthesized according to Reaction Formula 2 below.

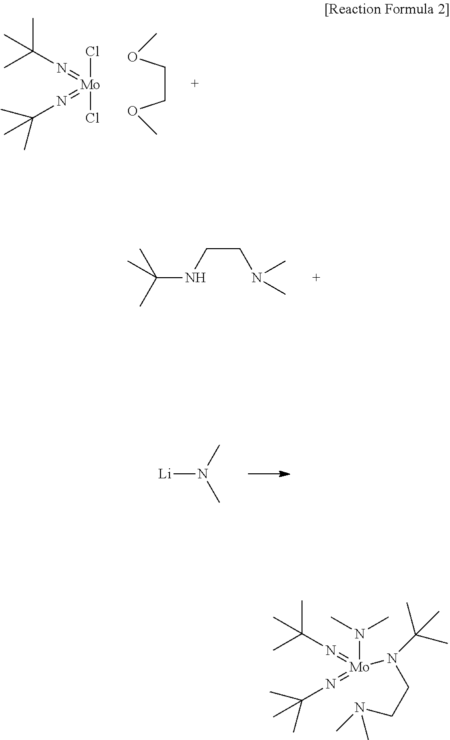

Specifically, 95.5 g (239.2 mmol) of (tBuN=)₂MoCl₂DME was added to a 1 L Schlenk flask, then 160 ml of anhydrous toluene was added thereto, and cooling was performed to −5° C. using ethanol and dry ice.

12.2 g (239.2 mmol) of lithium dimethylamine [LiDMA] dissolved in 30 ml of toluene was added dropwise through a cannula to a 1 L Schlenk flask, stirred for 2 hours at room temperature, and the synthesis was confirmed through NMR.

Next, 38 g of separately synthesized Li-TBDMAE was dissolved in hexane, and was added at −5° C. in the 1 L Schlenk flask dropwise. Here, the abbreviation TBDMAE refers to 1-(tert-butylamino)-2-(dimethylamino)ethane. After the reaction was terminated through NMR, the solvent was removed by filtration.

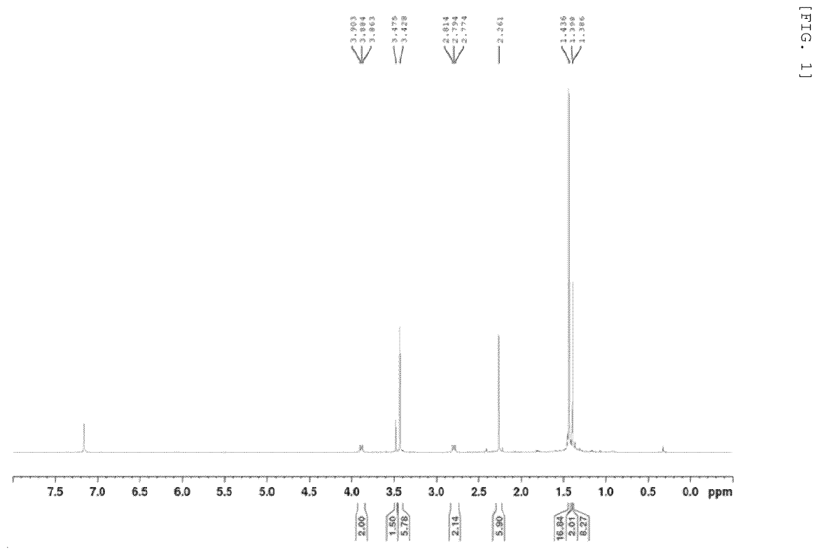

The obtained compound was purified through a purification column, and 20 g (yield: 30 wt %) of pure (tBuN=)₂Mo (TBDMAE) (DMA) was obtained. The results of ¹H NMR analysis are shown in FIG. 1 below.

As shown in FIG. 1, through ¹H NMR analysis, it was confirmed that the synthesized material was the intended material, (tBuN=)₂Mo(TBDMAE) (DMA).

### Synthesis Example 3: Synthesis of (tBuN=)₂Mo(TBDMAE) (tBuO)

Using (tBuN=)₂MoCl₂(DME) obtained in Synthesis Example 1, (tBuN=)₂Mo(TBDMAE) (tBuO) was synthesized according to Reaction Formula 3 below.

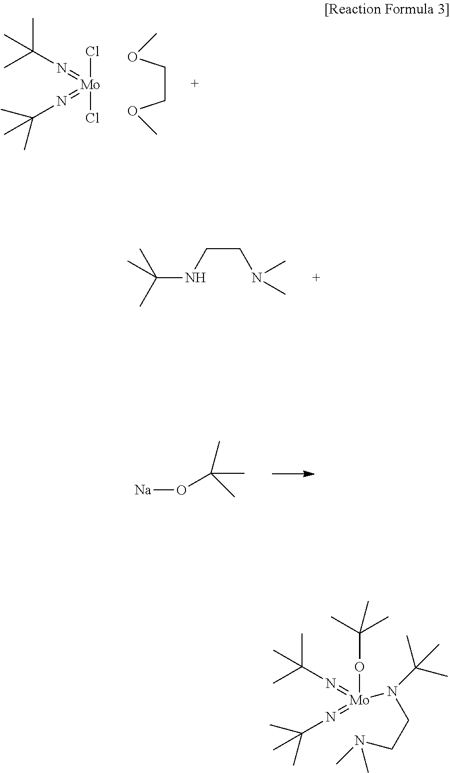

Specifically, 4.43 mL (25 mmol) of TBDMAE and 30 mL of anhydrous hexane were stirred in a 100 mL Schlenk flask, and 10 mL (25 mmol) of n-BuLi was added thereto at 0° C. After stirring for 30 minutes, 2.41 g (25 mmol) of sodium tert-butoxide was mixed. Here, the abbreviation TBDMAE stands for 1-(tert-butylamino)-2-(dimethylamino)ethane.

The mixture, 10 g (25 mmol) of (tBuN=)₂MoCl₂ (DME), and 50 mL of anhydrous toluene were placed in a 250 mL Schlenk flask, cooled to below 0° C., and then stirred at room temperature for 12 hours.

In the 250 mL Schlenk flask, 38 g of Li-TBDMAE, which was separately synthesized, was dissolved in hexane and then added dropwise at −5° C.

The stirred solution was filtered, and the filtrate was depressurized to obtain (tBuN=)₂Mo(TBDMAE) (tBuO).

The obtained crude (tBuN=)₂Mo(TBDMAE) (tBuO) was purified to obtain 5 g (yield: 50 wt %) of a brown liquid, and the result of ¹H NMR analysis confirmed that the compound indicated as (tBuN=)₂Mo(TBDMAE) (tBuO) to be manufactured was synthesized.

### [Test Example 1] Confirmation of the Properties of Thin Film Precursor Compounds

The properties of the thin film precursor compounds prepared in Synthesis Examples 1 and 2 were confirmed at 20° C. and 1 atm. As a result, both compounds were in a liquid state and had high volatility.

### [Test Example 2] Thermogravimetric Analysis (TG Analysis) of Thin Film Precursor Compounds

Thermogravimetric analysis (TG analysis) of the thin film precursor compounds prepared in Synthesis Examples 1 and 2 was performed.

The instrument used for thermogravimetric analysis (TGA) was a TGA/DSC 1 STARe System from Mettler Toledo using a 50 μL alumina crucible. The contents of all samples ranged from 8 to 11 mg, and measurements were performed at temperatures from 30° C. to 500° C.

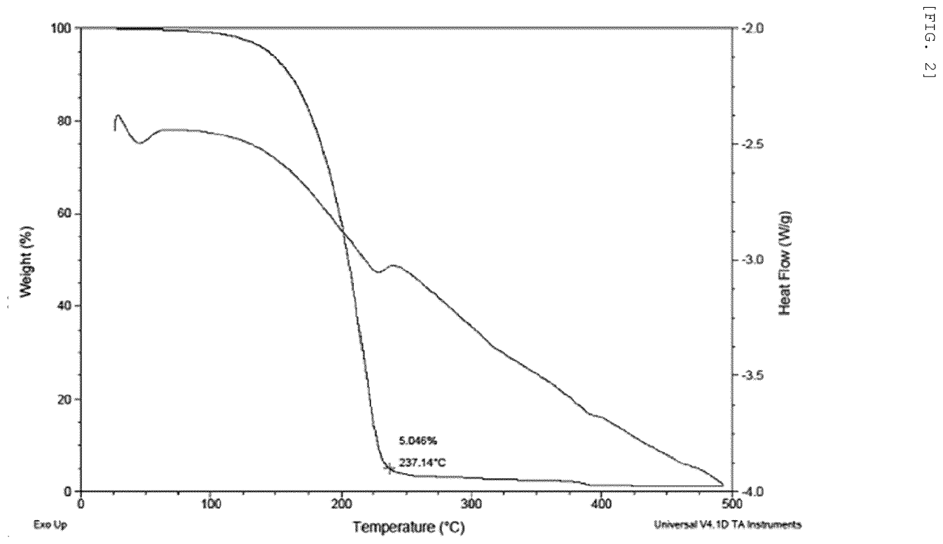

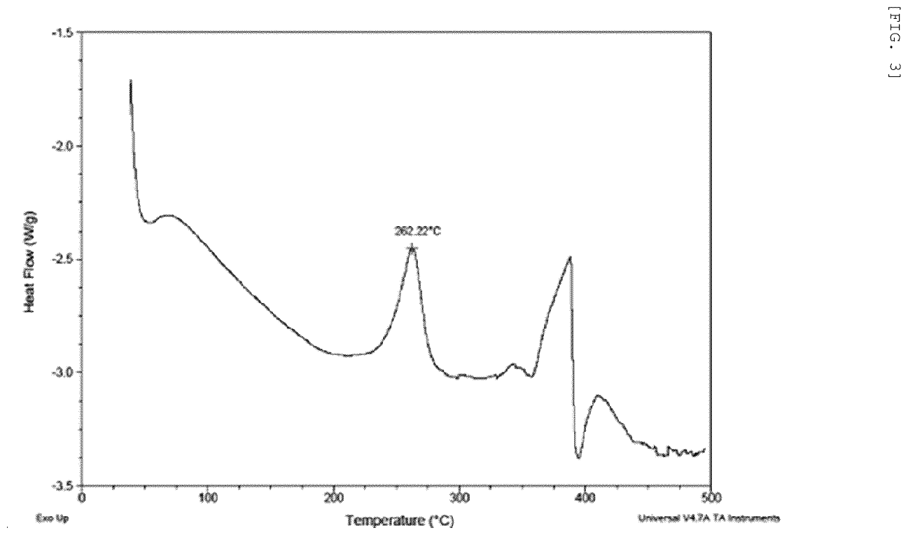

The results of the thermogravimetric analysis are shown in FIGS. 2 and 3 below. FIG. 2 below is a diagram showing the results of thermogravimetric analysis (DSC-TG analysis) of a thin film precursor compound synthesized in Synthesis Example 2, and FIG. 3 below is a diagram showing the results of differential scanning calorimetry (DSC) analysis of a thin film precursor compound synthesized in Synthesis Example 2.

As shown in FIGS. 2 and 3, the thin film precursor compound (tBuN=)₂Mo(TBDMAE) (DMA) obtained in Synthesis Example 2 was confirmed to have T½ of 118° C. and Tend of 237° C., indicating excellent thermogravimetric analysis values. In addition, it can be confirmed that the thermogravimetric analysis value of the thin film precursor compound (tBuN=)₂Mo(TBDMAE) (tBuO) obtained in Synthesis Example 3 is larger than that of the thin film precursor compound (tBuN=)₂Mo(TBDMAE) (DMA) obtained in Synthesis Example 2.

Additionally, heat flow analysis results show that the thin film precursor compound of the present invention is decomposed into one pattern (see blue ink graph in FIG. 2 below).

### EXAMPLES

### Examples 1 to 4

The thin film precursor compound described in Table 1 was placed in a canister and supplied to a vaporizer using a liquid mass flow controller (LMFC) at room temperature.

The thin film precursor compound vaporized in a vapor phase from the vaporizer was introduced into a deposition chamber loaded with a substrate, and then film formation was performed by atomic layer deposition (ALD) using a deposition apparatus shown in FIG. 4 under the deposition temperature conditions described in Table 1.

Specific deposition conditions are additionally shown in Table 2 below.

TABLE 1

| | | Deposition |
|---|---|---|
| Classification | Thin film precursor compound | temperature (° C.) |
| Example 1 | (tBuN═)₂Mo(TBDMAE)(DMA) | 350 |
| Example 2 | (tBuN═)₂Mo(TBDMAE)(DMA) | 400 |
| Example 3 | (tBuN═)₂Mo(TBDMAE)(tBuO) | 350 |
| Example 4 | (tBuN═)₂Mo(TBDMAE)(tBuO) | 400 |

TABLE 2
Deposition conditions

| | |
|---|---|
| Can. Temp (° C.) | 100 |
| Working pressure (torr) | 5.2 |
| NH₃ (sccm) | 1000 |
| Fill / Purge (sccm) | 1000 / 1500 |
| Recipe (s) | 2-4-3-6 |

The thin film precursor compound was placed in a stainless steel canister and supplied to a vaporizer heated to 150° C. at a flow rate of 0.05 g/min using a liquid mass flow controller (LMFC) at room temperature. Atomic layer deposition was performed by fixing the precursor injection time from the vaporizer to the chamber at 2 seconds, the precursor purge time at 4 seconds, the NH₃ injection time at 3 seconds, and the NH₃ purge time at 6 seconds (see Table 2). First, a silicon wafer was immersed in a diluted HF aqueous solution containing 50 wt % hydrofluoric acid (HF) and deionized water (DI) (H₂O) in a 3:2 ratio for 1 minute, then taken out and immersed in a DI solution for 4 minutes to remove a native oxide film and prepare a substrate with a pure silicon surface, which was then loaded into a chamber and heated to 300 to 350° C.

Next, the compound vaporized into a vapor phase by heating was injected into the deposition chamber loaded with the substrate using argon (Ar) gas as a carrier gas at a flow rate of 500 sccm for 2 seconds, and then argon (Ar) gas was supplied at 500 sccm for 4 seconds to perform argon purging. The pressure inside the reaction chamber was controlled to 2.5 Torr.

Next, 1000 sccm of NH₃ gas was injected for 3 seconds to form a nitride film, and then argon (Ar) gas was supplied at 500 sccm for 6 seconds to perform argon purging. At this time, the substrate on which a metal thin film is to be formed was heated to 300 to 450° C.

This process was repeated 200 times to form a MoN thin film, which is a self-limiting atomic layer.

### [Test Example 3] Film Formation Evaluation Through ALD Deposition of Thin Film Precursor Compounds

As a result of conducting film formation evaluation on the nitride films of Examples 1 to 4, the properties of the thin films according to the process temperature showed an ALD window range in the temperature range of 330 to 370° C., and the thin films were an ALD precursor having a constant thin film growth temperature in this range.

Specifically, the deposition rate and resistivity value (sheet resistance) were measured for the thin films obtained according to Examples 1 and 2.

Deposition rate (Thin film growth rate per cycle, Dep. Rate; GPC) (° C./cycle): GPC is an abbreviation for Growth Per Cycle. When measuring GPC, a thin film is formed by performing several cycles based on the supply of precursors, reactants, and purge gas as one cycle. The optical thickness of the formed thin film was measured using an ellipsometer, and the growth rate of the thin film formed per cycle was calculated from the total thickness of the formed thin film. The results are shown in Table 3 below.

Sheet resistance (Re) (uΩ·cm): The surface resistance of a material was measured using a 4-point probe method, and the surface resistance was calculated by inputting a correction coefficient.

Specifically, using the CMT-SERIES model of MICRONICS as a 4-point probe equipment, four probes were placed on the specimen surface, current was applied to the outer probes, voltage was specified to the middle probe to obtain the resistance value, and the resistance value was read by the CMT-SR1000NH system.

In addition, the correction factor is calculated using three coefficients: sample size, thin film thickness, and specific temperature. The sample size coefficient was applied as 4.532, which is a value usually applied to samples with a diameter of 40 mm or more. The thin film thickness coefficient was applied as 1, which is a value usually applied when the thin film thickness is less than about 400 μm. The temperature was calculated from Equation 1 below by utilizing the temperature coefficient of the sample, which is close to 1 when the temperature is about 23° C.

$$Correction factor ( C . F ) = cf 1 \times cf 2 \times cf 3 \qquad [ Equation 1 ]$$

The resistance value read from the CMT-SR1000NH system and the correction factor (C.F.) calculated from Equation 1 were substituted into Equation 2 below to calculate the sheet resistance unit, ohm/sq, and are summarized in Table 3 below.

$$Resistance value ( ohm ) \times Correction factor ( C . F ) = Sheet resistance ( ohm / sq ) \qquad [ Equation 2 ]$$

TABLE 3

| | Example 1 | Example 2 |
|---|---|---|
| | (Deposition | (Deposition |
| Process Temp. | temperature: 350° C.) | temperature: 400° C.) |
| GPC (Å/cy) | 0.74 | 1.81 |
| Rs (uΩcm) | 5.452 | 4.646 |

As shown in Table 3, in the case of the thin film precursor compound according to the present invention, it was confirmed that the thin film precursor compound had excellent thermal stability at deposition temperatures of 350° C. and 400° C., respectively, and provided a high deposition rate when deposited at low temperatures. In addition, it was confirmed that the sheet resistance value as a film characteristic at deposition temperatures of 350° C. and 400° C. showed a significant level when the resistance value was corrected by considering the specimen thickness.

In addition, as shown in Table 3, comparing the cases of deposition temperatures of 350° C. and 400° C., the deposition rate was 0.74 A/cycle when deposited at 350° C., and the deposition rate increased by nearly 144% to 1.81 A/cycle when the deposition temperature was increased to 400° C.

Compared to Example 1, in Example 2, the deposition rate increased. In this case, unlike the prior art, when the deposition rate increased, impurities did not increase, but rather, an unexpected phenomenon occurred in which impurities decreased, which could provide another great advantage when linked to the production capacity (through-put) aspect.

### [Test Example 4] Analysis of Cross-Sectional Thickness of Thin Films Through ALD Deposition of Thin Film Precursor Compounds

The cross-sectional thickness and density of the thin film obtained in Test Example 3 were analyzed as follows.

Density of thin film (g/cm³): The X-ray reflectometry (XRR) analysis method was used. The X-ray reflectometry (XRR) analysis is a method to analyze the appearance that appears when X-rays are incident and reflected between a surface and an interface. This analysis method was applied to a thin film specimen to measure the physical properties such as film thickness, density, and surface and interface roughness of the thin film.

As a result of the measurement, Example 1 deposited at 350° C. had an average cross-sectional thickness of 43.4 A, and Example 2 deposited at 400° C. had an average cross-sectional thickness of 156.9 A.

### [Test Example 5] Measurement of Thin Film Thickness and Step Coverage of Thin Film Precursor Compounds

The cross-sectional thickness and step coverage of the thin film obtained in Test Example 3 were confirmed by taking TEM photographs. FIG. 5 below is a TEM photograph measuring the thickness of a cross-section of a thin film formed using the thin film precursor compound synthesized in Synthesis Example 2 using the deposition apparatus of FIG. 4. The left image corresponds to the deposition condition of 350° C., and the right image corresponds to the deposition condition of 400° C.

As shown in FIG. 5 below, the thickness of the thin film was confirmed to be uniform. When a film is formed at a specific deposition temperature, it can be seen that excellent conformality and uniformity and precise thickness control are possible by the self-limiting thin film growth mechanism.

In addition, the step coverage of the Mo thin films deposited in Examples 1 and 2 was confirmed using TEM, and it was confirmed that the step coverage was high in both cases.

### [Test Example 6] Analysis of Carbon Concentration in Thin Films Through ALD Deposition of Thin Film Precursor Compounds

The carbon concentration of the thin film obtained in Test Example 3 was analyzed as follows, and the results are shown in Table 4 below.

Carbon concentration: The constituent elements, composition ratio, and chemical bonding state within the thin film were confirmed through X-ray photoelectron spectrometer (XPS) depth profile analysis.

TABLE 4

| | Example 1 | Example 2 |
|---|---|---|
| | (Deposition | (Deposition |
| Process Temp. | temperature: 350° C.) | temperature: 400° C.) |
| Carbon concentration | 6.56 | 8.06 |
| (Constituent elements, | | |
| composition ratio, and | | |
| chemical bonding state | | |
| in thin film) | | |

As shown in Table 4, the X-ray photoelectron spectrometer (XPS) depth profile results for the thin films obtained in Examples 1 and 2 confirmed that the thin film were MoN thin films and provided significant carbon concentration.

1. A thin film precursor compound represented by Chemical Formula 2: 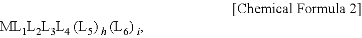
wherein M comprises one or more selected from the group consisting of molybdenum (Mo), tungsten (W), chromium (Cr), and seaborgium (Sg) and has charges of 0, +3, +4, +5, and +6 and a coordination number of 6, L₁, L₂, L₃, L₄, L₅, and L₆ are independently selected from the group consisting of NRaRb; ORc; NRc; CO; RdCp; amidinate; guadinate; ethylenediamine; propylenediamine; and a linear or cyclic saturated or unsaturated hydrocarbon having 3 to 15 carbon atoms and substituted with one or more nitrogen (N), oxygen (O), phosphorus (P), or sulfur (S), Cp is cyclopentadienyl, Ra, Rb, Rc, and Rd are independently hydrogen or alkyl having 1 to 12 carbon atoms, h and i are independently 0 or 1, an overall oxidation number of the compound is an integer from −2 to 6, and one or more ligands selected from L₁, L₂, L₃, L₄, L₅, and L₆ are linear or cyclic saturated or unsaturated hydrocarbons having 3 to 15 carbon atoms and substituted with one or more nitrogen (N), oxygen (O), phosphorus (P), or sulfur (S).

2. The thin film precursor compound according to claim 1, wherein the thin film precursor compound is a compound represented by Chemical Formula 3 or 4 below: 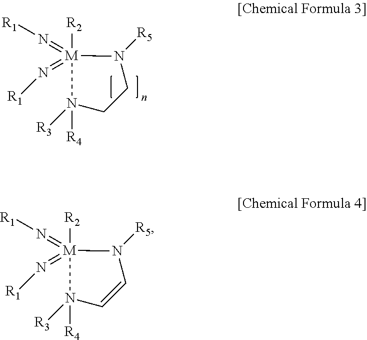
wherein, in Chemical Formulas 3 and 4, M comprises one or more selected from the group consisting of molybdenum (Mo), tungsten (W), chromium (Cr), and seaborgium (Sg) and has charges of 0, +3, +4, +5, and +6 and a coordination number of 6, R₁, R₂, R₃, R₄, and R₅ are independently selected from the group consisting of hydrogen, a dimethylamine group, a substituted or unsubstituted alkyl group having 1 to 7 carbon atoms, and a substituted or unsubstituted alkoxy group having 1 to 7 carbon atoms, and n is an integer from 0 to 2.

3. The thin film precursor compound according to claim 1, wherein the thin film precursor compound is obtained using a compound represented by Chemical Formula 1 below as an intermediate. 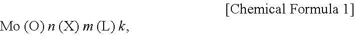
wherein Mo is molybdenum, O is oxygen, X is a halogen, L is a ligand, n is an integer from 0 to 2, m is an integer from 2 to 6, and k is an integer from 1 to 3.

4. The thin film precursor compound according to claim 3, wherein the ligand is a linear or cyclic saturated hydrocarbon having 3 to 15 carbon atoms and substituted with one or more nitrogen (N), oxygen (O), phosphorus (P), or sulfur (S) elements.

5. The thin film precursor compound according to claim 3, wherein the intermediate is (tBuN=)₂MoCl₂ (DAE),
wherein DAE is a dialkoxyethane having 1 to 15 carbon atoms.

6. The thin film precursor compound according to claim 1, wherein the thin film precursor compound is liquid and has volatility at 20° C. under 1 bar.

7. A method of forming a thin film, comprising injecting a thin film precursor compound represented by Chemical Formula 2 into a chamber and depositing the thin film precursor compound on a surface of a loaded substrate: 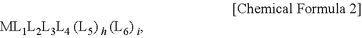
wherein M comprises one or more selected from the group consisting of molybdenum (Mo), tungsten (W), chromium (Cr), and seaborgium (Sg) and has charges of 0, +3, +4, +5, and +6 and a coordination number of 6, L₁, L₂, L₃, L₄, L₅, and L₆ are independently selected from the group consisting of NRaRb; ORc; NRc; CO; RdCp; amidinate; guadinate; ethylenediamine; propylenediamine; and a linear or cyclic saturated or unsaturated hydrocarbon having 3 to 15 carbon atoms and substituted with one or more nitrogen (N), oxygen (O), phosphorus (P), or sulfur (S), Cp is cyclopentadienyl, Ra, Rb, Rc, and Rd are independently hydrogen or alkyl having 1 to 12 carbon atoms, h and i are independently 0 or 1, an overall oxidation number of the compound is an integer from −2 to 6, and one or more ligands selected from L₁, L₂, L₃, L₄, L₅, and L₆ are linear or cyclic saturated or unsaturated hydrocarbons having 3 to 15 carbon atoms and substituted with one or more nitrogen (N), oxygen (O), phosphorus (P), or sulfur (S).

8. The method according to claim 7, wherein the depositing comprises vaporizing the thin film precursor compound and adsorbing the thin film precursor compound onto a surface of a substrate loaded into a chamber; purging an inside of the chamber with a purge gas; supplying a reaction gas into the chamber; and purging the inside of the chamber with a purge gas.

9. The method according to claim 7, wherein, in the depositing, the thin film precursor compound and the reaction gas are simultaneously injected into the substrate loaded into the chamber.

10. The method according to claim 7, wherein the depositing is performed by atomic layer deposition (ALD process), chemical vapor deposition (CVD process), plasma atomic layer deposition (PEALD process), or plasma chemical vapor deposition (PECVD process).

11. The method according to claim 9, wherein a nitrating agent, oxidizing agent, or reducing agent is used as the reaction gas.

12. The method according to claim 7, wherein the thin film comprises a metal nitride thin film, a metal oxide thin film, or a metal thin film.

13. A semiconductor substrate fabricated using the method according to claim 7.

14. A semiconductor device comprising the semiconductor substrate according to claim 13.
